(19) United States
(12) Patent Application Publication
(10) Pub. No.: US 2024/0395846 A1
(43) Pub. Date: Nov. 28, 2024

(54) SOLID-STATE IMAGE SENSOR AND METHOD FOR IMAGE SIGNAL PROCESSING

(71) Applicant: VisEra Technologies Company Limited, Hsin-Chu City (TW)

(72) Inventors: Kai-Hao CHANG, Hsin-Chu City (TW); Po-Hsiang WANG, Hsin-Chu City (TW); Yu-Chi CHANG, Hsin-Chu City (TW)

(21) Appl. No.: 18/321,394

(22) Filed: May 22, 2023

(51) Int. Cl. H01L 27/146; H04N 25/671

(52) U.S. Cl. CPC H01L 27/14645; H01L 27/14621; H01L 27/14636; H04N 25/671

(57) ABSTRACT

A solid-state image sensor is provided. The solid-state image sensor includes photoelectric conversion elements. The solid-state image sensor also includes a color filter layer disposed above the photoelectric conversion elements and the color filter layer includes a first color filter layer. The first color filter layer has a central region, a peripheral region adjacent to the central region, and a corner region diagonally arranged from the central region. The solid-state image sensor further includes a meta structure disposed on the color filter layer. The meta structure includes pillars. The pillars that correspond to the central region, the peripheral region, and the corner region have different arrangements.

### BACKGROUND OF THE INVENTION

### Field of the Invention

The embodiments of the present disclosure relate to a solid-state image sensor, and in particular, they relate to a solid-state image sensor that includes a meta structure.

### Description of the Related Art

Solid-state image sensors (such as charge-coupled device (CCD) image sensors, and complementary metal-oxide semiconductor (CMOS) image sensors) have been widely used in various image-capturing apparatuses such as digital still-image cameras, and digital video cameras. The light sensing portion in the solid-state image sensor may be formed at each of pixels, and signal electric charges may be generated according to the amount of light received in the light sensing portion. In addition, the signal electric charges generated in the light sensing portion may be transmitted and amplified, whereby an image signal is obtained.

Although existing solid-state image sensors have been generally adequate for their intended purposes, they have not been entirely satisfactory in all respects. For example, general hyperspectral image sensors have multispectral image cubes (e.g., image cubes of 256×256 pixels over 32 bands in the spectral range of about 600-1000 nm) that need large volumes. Such large volumes cannot be applied to smaller electronic devices such as mobile phones and smart watches.

### BRIEF SUMMARY OF THE INVENTION

The solid-state image sensor according to the embodiments of the present disclosure includes a meta structure, the pillars that correspond to the central region, the peripheral region, and the corner region of the color filter layer have different arrangements. Therefore, the augmented spectroscopic information with medium linewidth (e.g., Δλ is about 15-50 nm) may be obtained by the solid-state image sensor without large multispectral image cubes.

Some embodiments of the present disclosure include a solid-state image sensor. The solid-state image sensor includes photoelectric conversion elements. The solid-state image sensor also includes a color filter layer disposed above the photoelectric conversion elements and the color filter layer includes a first color filter layer. The first color filter layer has a central region, a peripheral region adjacent to the central region, and a corner region diagonally arranged from the central region. The solid-state image sensor further includes a meta structure disposed on the color filter layer. The meta structure includes pillars. The pillars that correspond to the central region, the peripheral region, and the corner region have different arrangements.

In some embodiments, the pillars correspond to the central region.

In some embodiments, the pillars are divided into a first pillar, second pillars, and third pillars with different diameters and form an array.

In some embodiments, the second pillars are arranged adjacent to the first pillar, and the third pillars are diagonally arranged from the first pillar. The diameter of the first pillar is smaller than the diameter of each second pillar, and the diameter of each second pillar is smaller than the diameter of each third pillar.

In some embodiments, the pillars correspond to the central region and the corner region, and the pillars have the same diameter.

In some embodiments, the pillars correspond to the central region, the peripheral region, and the corner region.

In some embodiments, the pillars are divided into a first pillar that corresponds to the central region, second pillars that correspond to the peripheral region, and third pillars that correspond to the corner region, and the first pillar, the second pillars, and the third pillars have different diameters.

In some embodiments, the diameter of the first pillar is smaller than the diameter of each third pillar, and the diameter of each third pillar is smaller than the diameter of each second pillar.

In some embodiments, the meta structure includes additional caps disposed on the first pillar and the third pillars.

In some embodiments, the first color filter layer has first color filter segments, the first color filter segments in the central region form an n×n array, and the number of first color filter segments in the peripheral region is 4n, and n is an integer greater than or equal to 1.

In some embodiments, n is 2, and each first color filter segment in the central region is disposed under the pillars that are divided into a first pillar, second pillars arranged adjacent to the first pillar, and third pillars diagonally arranged from the first pillar.

In some embodiments, the diameter of the first pillar is smaller than the diameter of each second pillar, and the diameter of each second pillar is smaller than the diameter of each third pillar.

In some embodiments, n is 2, and the pillars are divided into first pillars that correspond to the central region, second pillars that correspond to the peripheral region, and third pillars that correspond to the corner region, and the first pillar, the second pillars, and the third pillars have different diameters.

In some embodiments, the diameter of each first pillar is equal to the diameter of each third pillar, and is smaller than the diameter of each second pillar.

In some embodiments, n is 3, and the pillars are divided into first pillars that form an x shape and correspond to the middle of the central region, second pillars that surround the first pillars, and third pillars that correspond to four corners of the central region.

In some embodiments, the diameter of each first pillar is smaller than the diameter of each second pillar, and the diameter of each second pillar is smaller than the diameter of each third pillar.

In some embodiments, n is 3, and the pillars are divided into first pillars that form a p×p array and correspond to the middle of the first color filter layer, second pillars that surround the first pillars, and third pillars that form a q×q array and correspond to four corners of the first color filter layer, and p and q are integers greater than or equal to 2.

In some embodiments, the diameter of each first pillar is equal to the diameter of each third pillar, and is smaller than the diameter of each second pillar.

In some embodiments, the color filter layer further includes a second color filter layer that is adjacent to the first color filter layer and corresponds to different colors than the first color filter layer, and the pillars have different heights on the first color filter layer and the second color filter layer.

Some embodiments of the present disclosure include a method for an image signal processing. The method for the image signal processing includes the following steps. A raw image is input into a solid solid-state image sensor. The solid-state image sensor includes photoelectric conversion elements. The solid-state image sensor also includes a color filter layer disposed above the photoelectric conversion elements and the color filter layer includes a first color filter layer. The first color filter layer has a central region, a peripheral region adjacent to the central region, and a corner region diagonally arranged from the central region. The solid-state image sensor further includes a meta structure disposed on the color filter layer. The meta structure includes pillars. The pillars that correspond to the central region, the peripheral region, and the corner region have different arrangements. An image correction is performed on the raw image, so that the solid-state image sensor obtains a normal signal and a specific signal with matrix operation. The normal signal and the specific signal are integrated to form a specific model. The specific model is output from the solid solid-state image sensor to obtain a prediction map.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a partial cross-sectional view illustrating the solid-state image sensor according to some embodiments of the present disclosure.

FIG. 1B is a partial top view illustrating the solid-state image sensor according to some embodiments of the present disclosure.

FIG. 1C is an enlarge view of region E1 in FIG. 1B.

FIG. 2 is a partial top view illustrating the color filter layer in FIG. 1A and FIG. 1B.

FIG. 3A is a schematic diagram of signal distribution of light passing through the solid-state image sensor.

FIG. 3B illustrates quantum efficiency (QE) spectra of the blue color filter segments.

FIG. 3C illustrates a residual quantum efficiency (QE) spectrum of the blue color filter segments by the signal processing for spectral information.

FIG. 3D illustrates quantum efficiency (QE) spectra of the green color filter segments.

FIG. 3E illustrates a residual quantum efficiency (QE) spectrum of the green color filter segments by the signal processing for spectral information.

FIG. 3F illustrates quantum efficiency (QE) spectra of the red color filter segments.

FIG. 3G illustrates a residual quantum efficiency (QE) spectrum of the red color filter segments by the signal processing for spectral information.

FIG. 4A is a partial cross-sectional view illustrating the solid-state image sensor according to some other embodiments of the present disclosure.

FIG. 4B is a partial top view illustrating the solid-state image sensor according to some other embodiments of the present disclosure.

FIG. 4C is an enlarge view of the red color filter segment R1 in FIG. 4B.

FIG. 4D is an enlarge view of the red color filter segment R2 in FIG. 4B.

FIG. 4E is an enlarge view of the red color filter segment R3 in FIG. 4B.

FIG. 5A is a partial cross-sectional view illustrating the solid-state image sensor according to some other embodiments of the present disclosure.

FIG. 5B is a partial top view illustrating the solid-state image sensor according to some other embodiments of the present disclosure.

FIG. 5C is an enlarge view of the red color filter segment R1 in FIG. 5B.

FIG. 5D is an enlarge view of the red color filter segment R2 in FIG. 5B.

FIG. 5E is an enlarge view of the red color filter segment R3 in FIG. 5B.

FIGS. 5F-5H respectively illustrate the three-dimensional schematic diagrams of the pillars.

FIG. 6 is a schematic diagram of signal distribution of light passing through the solid-state image sensor according to some embodiments of the present disclosure.

FIG. 7 is a partial top view illustrating the color filter layer of the solid-state image sensor.

FIG. 8A is a partial top view illustrating the solid-state image sensor according to some embodiments of the present disclosure.

FIG. 8B is an enlarge view of the red color filter layer and the corresponding pillars.

FIG. 9A is a partial top view illustrating the solid-state image sensor according to some other embodiments of the present disclosure.

FIG. 9B is an enlarge view of the red color filter layer and the corresponding pillars in FIG. 9A.

FIG. 10A is a partial top view illustrating the solid-state image sensor according to some other embodiments of the present disclosure.

FIG. 10B is an enlarge view of the red color filter layer and the corresponding pillars.

FIG. 11 is a partial top view illustrating the color filter layer of the solid-state image sensor.

FIG. 12A is a partial top view illustrating the solid-state image sensor according to some embodiments of the present disclosure.

FIG. 12B is an enlarge view of the red color filter layer and the corresponding pillars.

FIG. 13A is a partial top view illustrating the solid-state image sensor according to some other embodiments of the present disclosure.

FIG. 13B is an enlarge view of the red color filter layer and the corresponding pillars in FIG. 13A.

FIG. 14A is a partial top view illustrating the solid-state image sensor according to some other embodiments of the present disclosure.

FIG. 14B is an enlarge view of the red color filter layer and the corresponding pillars in FIG. 14A.

FIG. 15 is a flow chart illustrating a method for an image signal processing.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

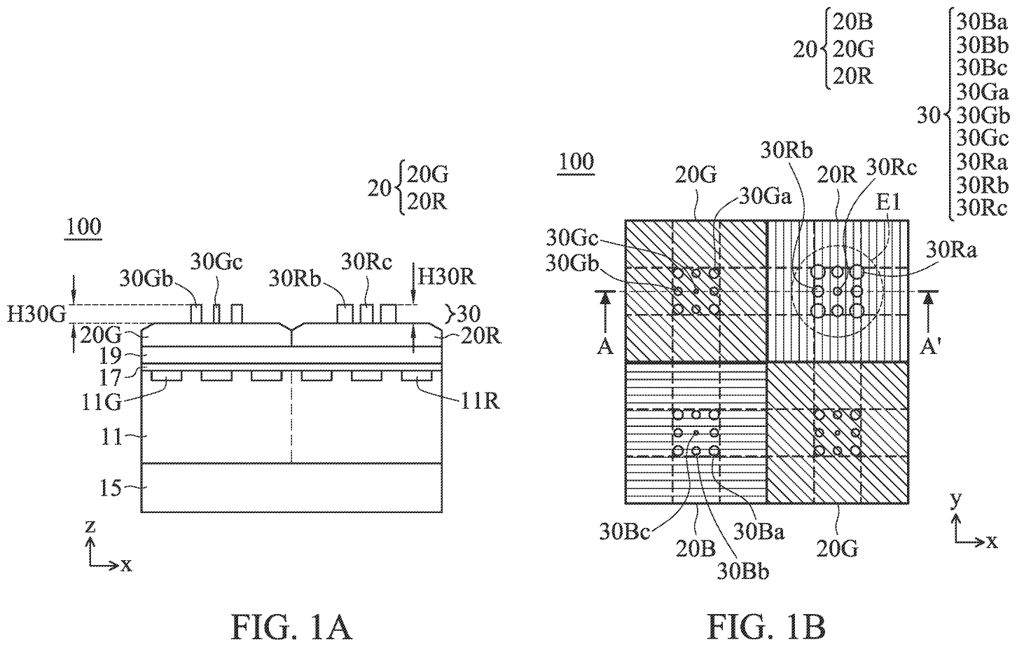

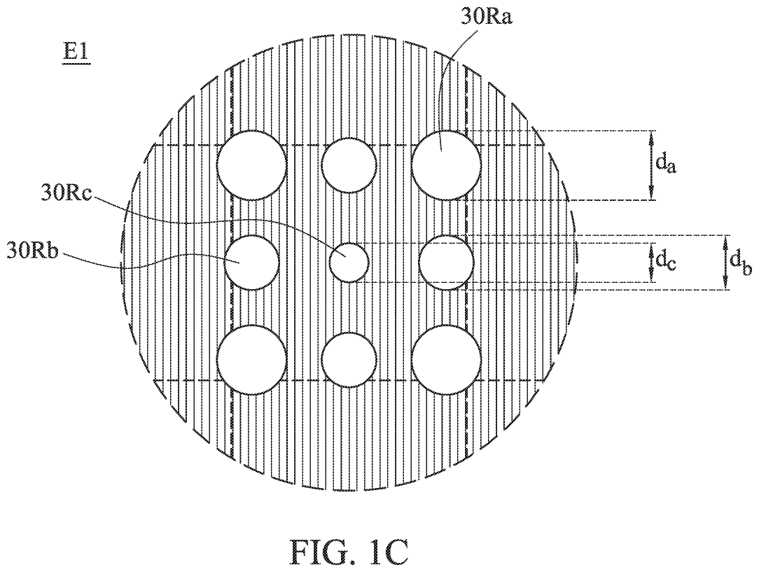

FIG. 1A is a partial cross-sectional view illustrating the solid-state image sensor 100 according to some embodiments of the present disclosure. FIG. 1B is a partial top view illustrating the solid-state image sensor 100 according to some embodiments of the present disclosure. For example, FIG. 1A may be the partial cross-sectional view of the solid-state image sensor 100 along line A-A′ in FIG. 1B, but the present disclosure is not limited thereto. FIG. 1C is an enlarge view of region E1 in FIG. 1B. It should be noted that some components of the solid-state image sensor 100 have been omitted in FIG. 1A, FIG. 1B, and FIG. 1C for the sake of brevity.

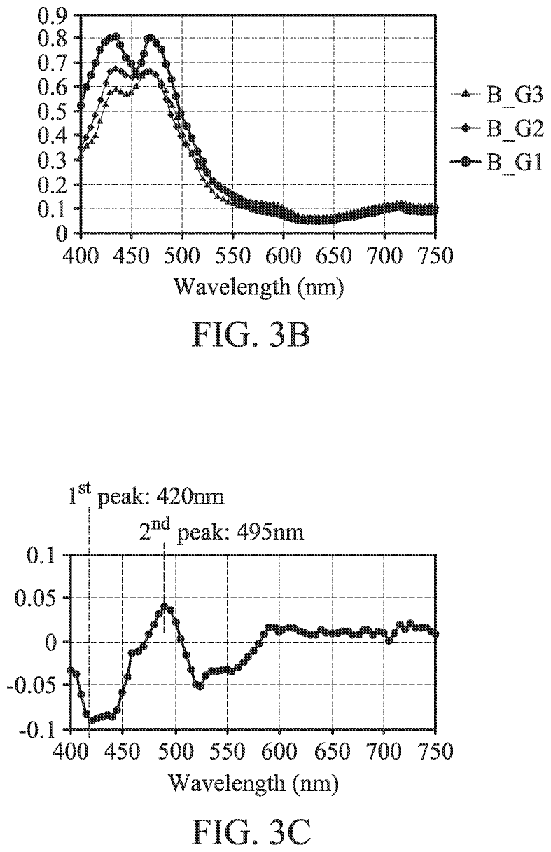

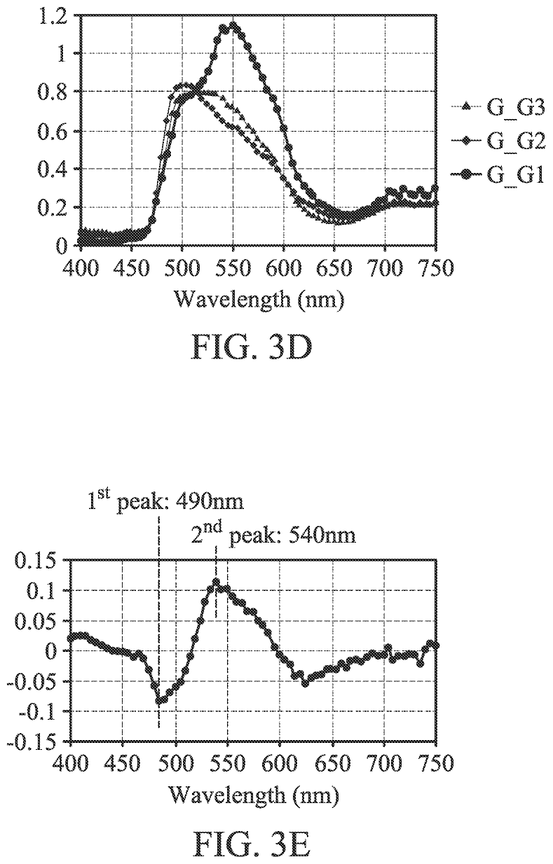

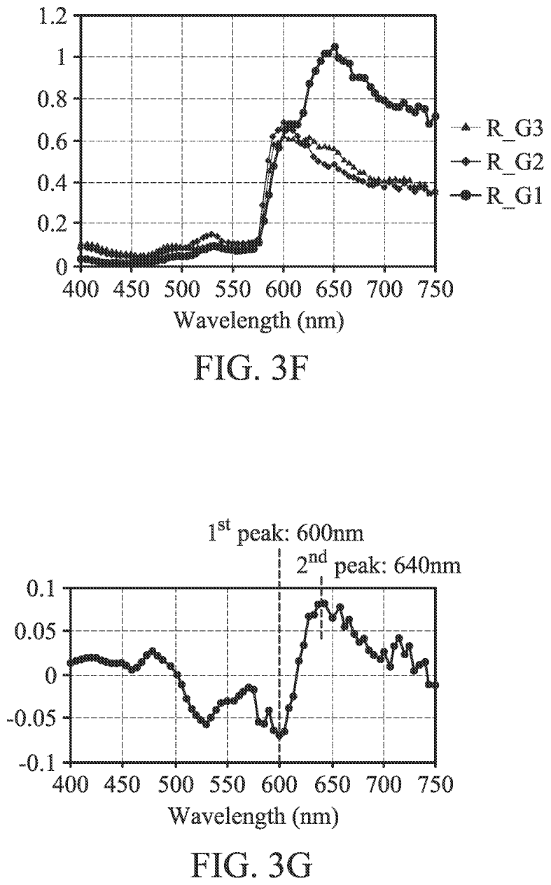

In some embodiments, the solid-state image sensor 100 may be a complementary metal-oxide semiconductor (CMOS) image sensor or a charge coupled device (CCD) image sensor, but the present disclosures is not limited thereto. As shown in FIG. 1A, in some embodiment, the solid-state image sensor 100 includes a semiconductor substrate 11 that may be, for example, a wafer or a chip. Referring to FIG. 1A, in some embodiment, the solid-state image sensor 100 includes photoelectric conversion elements 11G, and 11R (and 11B shown in FIG. 3A) such as photodiodes that are formed in the semiconductor substrate 11.

For example, the photoelectric conversion elements 11B may be used for receiving blue light, the photoelectric conversion elements 11G may be used for receiving green light, and the photoelectric conversion elements 11R may be used for receiving red light, but the present disclosure is not limited thereto. The solid-state image sensor 100 may include other photoelectric conversion elements that are used for receiving, for example, yellow light, white light, cyan light, magenta light, or IR/NIR light, which may be adjusted depending on actual needs.

Moreover, the photoelectric conversion elements 11B, 11G, and 11R in the semiconductor substrate 11 may be isolated from each other by isolation structures (not shown) such as shallow trench isolation (STI) regions or deep trench isolation (DTI) regions. The isolation structures may be formed in the semiconductor substrate 11 using etching process to form trenches and filling the trenches with an insulating or dielectric material.

As shown in FIG. 1A, in some embodiment, the solid-state image sensor 100 includes a wiring layer 15 disposed on the semiconductor substrate 11, but the present disclosure is not limited thereto. The wiring layer 15 may be an interconnect structure that includes multiple conductive lines and vias embedded in multiple dielectric layers, and may further include various electric circuits required for the solid-state image sensor 100. In some other embodiments, the semiconductor substrate 11 and the wiring layer 15 shown in FIG. 1A may be inverted.

As shown in FIG. 1A, in some embodiments, the solid-state image sensor 100 includes a high dielectric-constant (high-κ) film 17 disposed on the semiconductor substrate 11 and covering the photoelectric conversion elements 11B, 11G, and 11R. The high-K film 17 may include hafnium oxide (HfO₂), hafnium tantalum oxide (HfTaO), hafnium titanium oxide (HfTiO), hafnium zirconium oxide (HfZrO), tantalum pentoxide (Ta₂O₅), any other suitable high-κ dielectric material, or a combination thereof, but the present disclosure is not limited thereto. The high-film 17 may be formed by a deposition process. The deposition process is, for example, chemical vapor deposition (CVD), plasma enhanced chemical vapor deposition (PECVD), atomic layer deposition (ALD), or another deposition technique. Moreover, the high-κ film 17 may have a high-refractive index and a light-absorbing ability.

As shown in FIG. 1A, in some embodiments, the solid-state image sensor 100 includes a buffer layer 19 formed on the high-κ film 17. The buffer layer 19 may include silicon oxides, silicon nitrides, silicon oxynitrides, any other suitable insulating material, or a combination thereof, but the present disclosure is not limited thereto. The buffer layer 19 may be formed by a deposition process. The deposition process is, for example, spin-on coating, chemical vapor deposition, flowable chemical vapor deposition (FCVD), plasma enhanced chemical vapor deposition, physical vapor deposition (PVD), or another deposition technique.

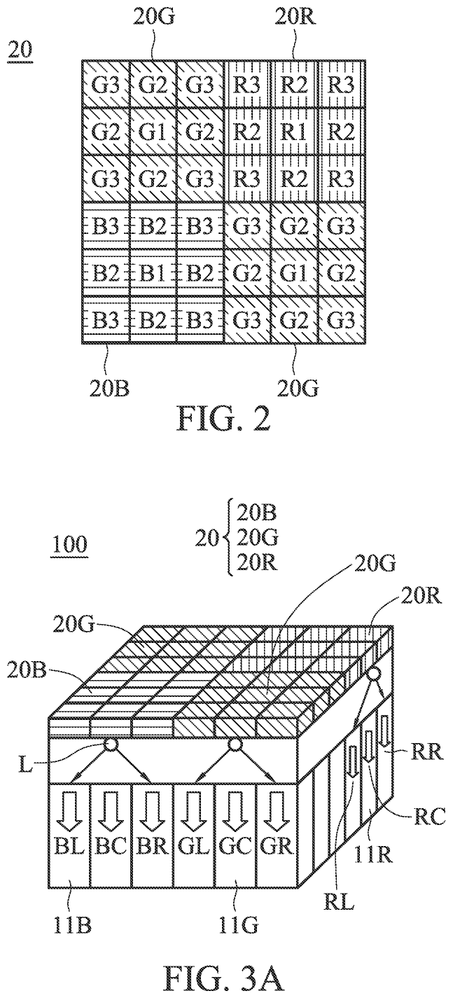

Referring to FIG. 1A and FIG. 1B, in some embodiments, the solid-state image sensor 100 includes a color filter layer 20 disposed above the photoelectric conversion elements 11B, 11G, and 11R. FIG. 2 is a partial top view illustrating the color filter layer 20 in FIG. 1A and FIG. 1B. As shown in FIG. 1A, FIG. 1B, and FIG. 2, in some embodiments, the color filter layer 20 includes a red color filter layer 20R that corresponds to the photoelectric conversion elements 11R, a green color filter layer 20G that corresponds to the photoelectric conversion elements 11G, and a blue color filter layer 20B that corresponds to the photoelectric conversion elements (not shown in FIG. 1A).

As shown in FIG. 2, the red color filter layer 20R has (or is divided into) red color filter segments R1, R2, and R3. In some embodiment, the red color filter layer 20R has a central region (that corresponds to the red color filter segment R1), a peripheral region (that corresponds to the red color filter segments R2) adjacent to the central region, and a corner region (that corresponds to the red color filter segments R3) diagonally arranged from the central region.

As shown in FIG. 2, the green color filter layer 20G has (or is divided into) green color filter segments G1, G2, and G3. Similarly, in some embodiment, the green color filter layer 20G has a central region (that corresponds to the green color filter segment G1), a peripheral region (that corresponds to the green color filter segments G2) adjacent to the central region, and a corner region (that corresponds to the green color filter segments G3) diagonally arranged from the central region.

As shown in FIG. 2, the blue color filter layer 20B has (or is divided into) blue color filter segments B1, B2, and B3. Similarly, in some embodiment, the blue color filter layer 20B has a central region (that corresponds to the blue color filter segment B1), a peripheral region (that corresponds to the blue color filter segments B2) adjacent to the central region, and a corner region (that corresponds to the blue color filter segments B3) diagonally arranged from the central region.

As shown in FIG. 2, the green color filter layer 20G is adjacent to the red color filter layer 20R and the blue color filter layer 20B and corresponds to different colors than the red color filter layer 20R and the blue color filter layer 20B. Moreover, the red color filter layer 20R and the blue color filter layer 20B are diagonally arranged, but the present disclosure is not limited thereto. The red color filter segments R1, R2, and R3 form a 3×3 array, the green color filter segments G1, G2, and G3 form two 3×3 arrays, and the blue color filter segments B1, B2, and B3 form a 3×3 array. In other words, the red color filter segments R1, R2, and R3, the green color filter segments G1, G2, and G3, and the blue color filter segments B1, B2, and B3 may be a 9C RGB mosaic pattern, but the present disclosure is not limited thereto.

Referring to FIG. 1A and FIG. 1B, in some embodiments, the solid-state image sensor 100 includes a meta structure 30 disposed on the color filter layer 20, and the meta structure includes pillars (e.g., 30Ba, 30Bb, 30Bc, 30Ga, 30Gb, 30Gc, 30Ra, 30Rb, 30Rc). In some embodiments, the pillars that correspond to the central region, the peripheral region, and the corner region of the red color filter layer 20R (or the blue color filter layer 20B or the green color filter layer 20G) have different arrangements.

As shown in FIG. 1B and FIG. 2, in some embodiments, the pillars 30Ra, 30Rb, 30Rc correspond to the central region (that corresponds to the red color filter segment R1) of the red color filter layer 20R, but do not correspond to the peripheral region (that corresponds to the red color filter segments R2) and the corner region (that corresponds to the red color filter segments R3) of the red color filter layer 20R.

In some embodiments, the pillars 30Ra, 30Rb, 30Rc have different diameters and form an array (e.g., 3×3 array). As shown in FIG. 1B and FIG. 1C, in some embodiments, the pillars 30Rb are arranged adjacent to the pillar 30Ra, and the pillars 30Ra are diagonally arranged from the pillar 30Rc. As shown in FIG. 1C, in some embodiments, the diameter d_{c} of the pillar 30Rc is smaller than the diameter d_{b} of each pillar 30Rb, and the diameter d_{b} of each pillar 30Rb is smaller than the diameter dₐ of each pillar 30Ra.

Similarly, in some embodiments, the pillars 30Ba, 30Bb, 30Bc correspond to the central region (that corresponds to the blue color filter segment R1) of the blue color filter layer 20B, but do not correspond to the peripheral region (that corresponds to the blue color filter segments B2) and the corner region (that corresponds to the blue color filter segments B3) of the blue color filter layer 20B. Moreover, the pillars 30Ba, 30Bb, 30Bc have different diameters and form an array (e.g., 3×3 array).

Similarly, in some embodiments, the pillars 30Ga, 30Gb, 30Gc correspond to the central region (that corresponds to the green color filter segment G1) of the green color filter layer 20G, but do not correspond to the peripheral region (that corresponds to the green color filter segments G2) and the corner region (that corresponds to the green color filter segments G3) of the green color filter layer 20G. Moreover, the pillars 30Ga, 30Gb, 30Gc have different diameters and form an array (e.g., 3×3 array).

FIG. 3A is a schematic diagram of signal distribution of light passing through the solid-state image sensor 100. It should be noted that some components of the solid-state image sensor 100 (e.g., the meta structure 30) have been omitted in FIG. 3A for the sake of brevity.

As shown FIG. 2 and FIG. 3A, light passing through the meta structure 30 and the blue color filter segment B3 may be transferred into signal BL or signal BR and to be sensed by the photoelectric conversion element 11B, and light passing through the meta structure 30 and the blue color filter segment B2 may be transferred into signal BC and to be sensed by the photoelectric conversion element 11B.

Similarly, light passing through the meta structure 30 and the green color filter segment G3 may be transferred into signal GL or signal GR and to be sensed by the photoelectric conversion element 11G, and light passing through the meta structure 30 and the green color filter segment G2 may be transferred into signal GC and to be sensed by the photoelectric conversion element 11G.

Moreover, light passing through the meta structure 30 and the red color filter segment R3 may be transferred into signal RL or signal RR and to be sensed by the photoelectric conversion element 11R, and light passing through the meta structure 30 and the red color filter segment R2 may be transferred into signal RC and to be sensed by the photoelectric conversion element 11R.

FIG. 3B illustrates quantum efficiency (QE) spectra of the blue color filter segments B1 (line B_G1), B2 (line B_G2), and B3 (line B_G3), and FIG. 3C illustrates a residual quantum efficiency (QE) spectrum of the blue color filter segments (e.g., B3-B2) by the signal processing for spectral information. FIG. 3D illustrates quantum efficiency (QE) spectra of the green color filter segments G1 (line G_G1), G2 (line G_G2), and G3 (line G_G3), and FIG. 3E illustrates a residual quantum efficiency (QE) spectrum of the green color filter segments (e.g., G3-G2) by the signal processing for spectral information. FIG. 3F illustrates quantum efficiency (QE) spectra of the red color filter segments R1 (line R_G1), R2 (line R_G2), and R3 (line R_G3), and FIG. 3G illustrates a residual quantum efficiency (QE) spectrum of the red color filter segments (e.g., R3-R2) by the signal processing for spectral information.

As shown in FIG. 3B and FIG. 3C, the augmented spectroscopic information with medium linewidth (e.g., λ is between about 1^{st} peak of 420 nm and about 2^{nd} peak of 495 nm) may be obtained by residual quantum efficiency (QE) spectrum of the blue color filter segments. As shown in FIG. 3D and FIG. 3E, the augmented spectroscopic information with medium linewidth (e.g., A is between about 1^{st} peak of 490 nm and about 2^{nd} peak of 540 nm) may be obtained by residual quantum efficiency (QE) spectrum of the green color filter segments. As shown in FIG. 3F and FIG. 3G, the augmented spectroscopic information with medium linewidth (e.g., λ is between about 1^{st} peak of 600 nm and about 2^{nd} peak of 640 nm) may be obtained by residual quantum efficiency (QE) spectrum of the red color filter segments.

In this embodiment, L shown in FIG. 3A may be regarded as a splitter. That is, the energy of a raw image may be redistributed by the splitter L (i.e., passing through the meta structure 30), so that the spectral augmentation may be obtained. For example, signal processing for spectral information may be as follows:

$$( \begin{matrix}G 0 \\ GX\end{matrix} ) = ( \begin{matrix}\frac{1}{3} & \frac{1}{3} & \frac{1}{3} \\ \frac{1}{3} & - \frac{2}{3} & \frac{1}{3}\end{matrix} ) ( \begin{matrix}GL \\ GC \\ GR\end{matrix} )$$

Here, G0 represents a broad band information (i.e., a normal signal) in green color filter layer 20G, and GX represents a narrow band information (i.e., a specific signal) (e.g., a narrow band between about 1^{st} peak of 490 nm and about 2^{nd} peak of 540 nm in FIG. 3E) in green color filter layer 20G. In other words, GX represents a specific narrow band in green color filter layer 20G scattered by the splitter L. Therefore, signal GL, signal GC, and signal GR may be, but not limited to, as follows:

$$\{ \begin{matrix}GL = G 0 + 0.5 GX \\ GC = G 0 - GX \\ GR = G 0 + 0.5 GX\end{matrix}$$

Similarly, signal BL, signal BC, and signal BR may be obtained by signal processing using B0 (i.e., a normal signal) and BX (i.e., a specific signal) (e.g., a narrow band between about 1^{st} peak of 420 nm and about 2^{nd} peak of 495 nm in FIG. 3C) in blue color filter layer 20B. Moreover, signal RL, signal RC, and signal RR may be obtained by signal processing using R0 (i.e., a normal signal) and RX (i.e., a specific signal) (e.g., a narrow band between about 1^{st} peak of 600 nm and about 2^{nd} peak of 640 nm in FIG. 3G) in red color filter layer 20R. However, the present disclosure is not limited thereto.

In this embodiment, the pillars have the same height on the green color filter layer 20G and the red color filter layer 20R (and the blue color filter layer 20B). In other words, the height H30G of the pillars 30Ga, 30Gb, 30Gc on the green color filter layer 20G may be equal to the height H30R of the pillars 30Ra, 30Rb, 30Rc on the red color filter layer 20R as shown in FIG. 1A, but the present disclosure is not limited thereto. In some other embodiments, the pillars have different heights on the red color filter layer 20R and the green color filter layer 20G (and the blue color filter layer 20B). For example, the height H30G of the pillars 30Ga, 30Gb, 30Gc on the green color filter layer 20G may be smaller than the height H30R of the pillars 30Ra, 30Rb, 30Rc on the red color filter layer 20R, and the height H30R of the pillars 30Ra, 30Rb, 30Rc on the red color filter layer 20R may be smaller than the height of the pillars 30Ba, 30Bb, 30Bc on the blue color filter layer 20B.

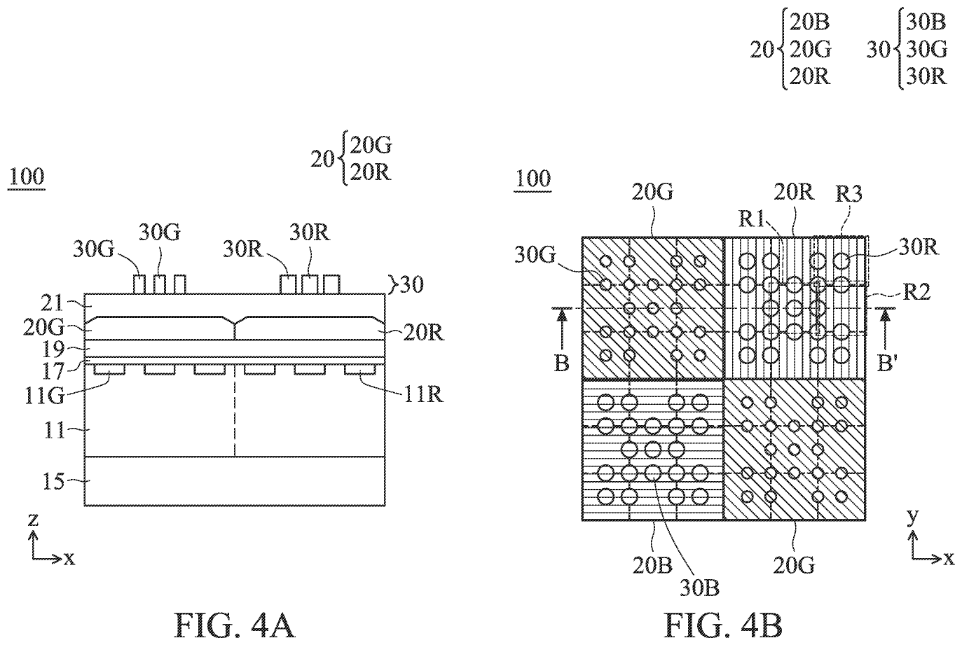

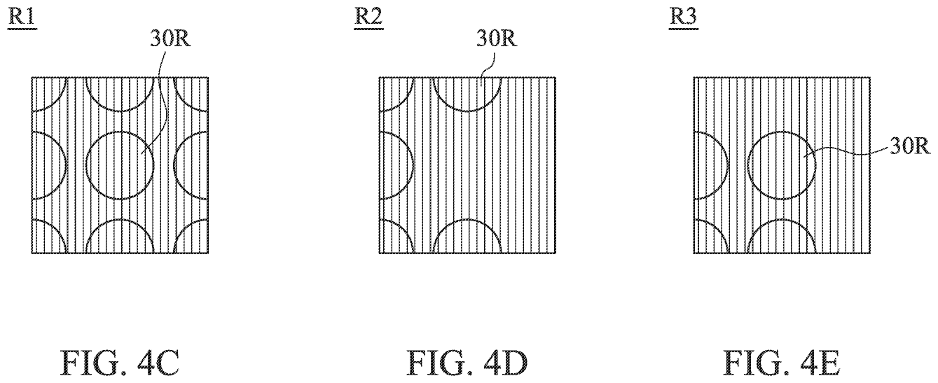

FIG. 4A is a partial cross-sectional view illustrating the solid-state image sensor 100 according to some other embodiments of the present disclosure. FIG. 4B is a partial top view illustrating the solid-state image sensor 100 according to some other embodiments of the present disclosure. For example, FIG. 4A may be the partial cross-sectional view of the solid-state image sensor 100 along line B-B′ in FIG. 4B, but the present disclosure is not limited thereto. FIG. 4C is an enlarge view of the red color filter segment R1 in FIG. 4B. FIG. 4D is an enlarge view of the red color filter segment R2 in FIG. 4B. FIG. 4E is an enlarge view of the red color filter segment R3 in FIG. 4B. It should be noted that some components of the solid-state image sensor 100 have been omitted in FIG. 4A to FIG. 4E for the sake of brevity.

As shown in FIG. 4A, in this embodiment, the solid-state image sensor 100 further includes a dielectric layer 21 disposed between the color filter layer 20 and the meta structure 30. For example, the dielectric layer 21 may include a transparent dielectric material with a refractive index from about 1.1 to about 2.0, but the present disclosure is not limited thereto. Moreover, the dielectric layer 21 may be formed by a deposition process and a (spin-) coating process (and a planarization processes, such as chemical mechanical polishing (CMP)), but the present disclosure is not limited thereto.

As shown in FIG. 4B (and FIG. 2), in some embodiments, the pillars 30R correspond to the central region (that corresponds to the red color filter segment R1) and the corner region (that corresponds to the red color filter segments R3) of the red color filter layer 20R, but do not correspond to the peripheral region (that corresponds to the red color filter segments R2) of the red color filter layer 20R.

Similarly, in some embodiments, the pillars 30B correspond to the central region (that corresponds to the blue color filter segment B1) and the corner region (that corresponds to the blue color filter segments B3) of the blue color filter layer 20B, but do not correspond to the peripheral region (that corresponds to the blue color filter segments B2) of the blue color filter layer 20B.

Similarly, in some embodiments, the pillars 30G correspond to the central region (that corresponds to the green color filter segment G1) and the corner region (that corresponds to the green color filter segments G3) of the green color filter layer 20G, but do not correspond to the peripheral region (that corresponds to the green color filter segments G2) of the green color filter layer 20G.

As shown in FIG. 4B and FIGS. 4C-4E, in some embodiments, the pillars 30R on the red color filter layer 20R have the same diameter. As shown in FIG. 4B, in some embodiments, the pillars 30B on the blue color filter layer 20B have the same diameter, and the pillars 30G on the green color filter layer 20G have the same diameter.

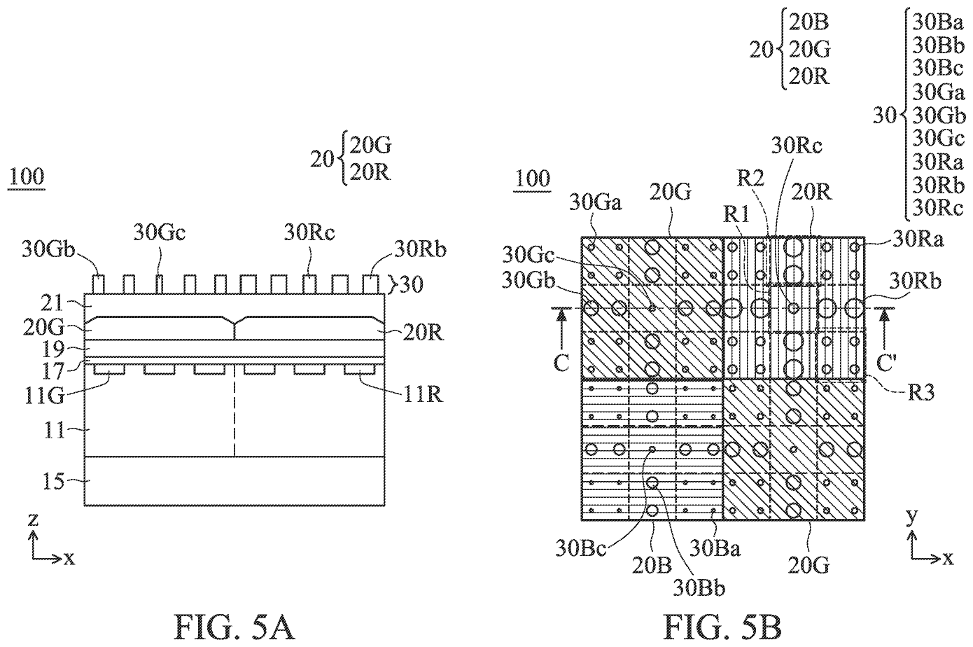

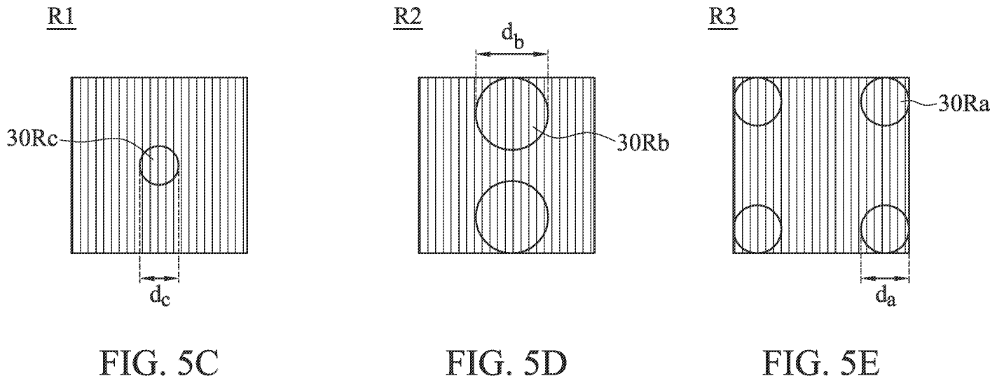

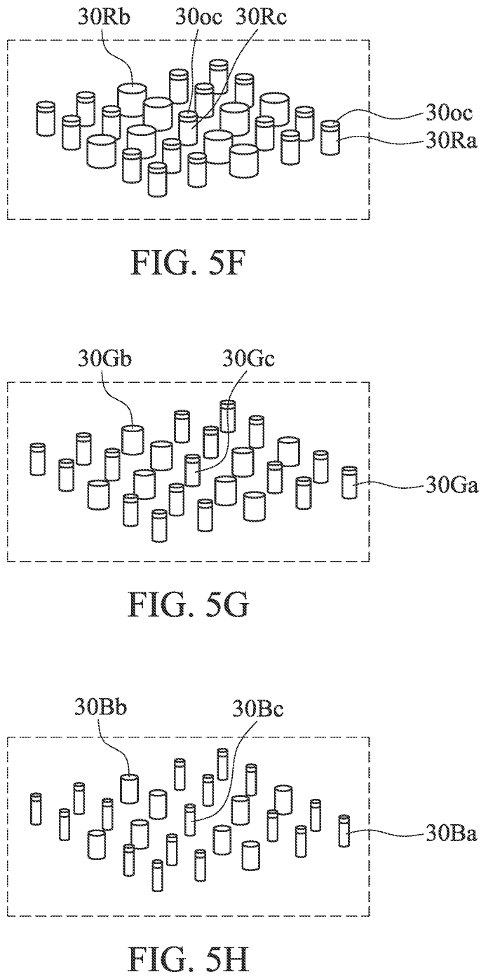

FIG. 5A is a partial cross-sectional view illustrating the solid-state image sensor 100 according to some other embodiments of the present disclosure. FIG. 5B is a partial top view illustrating the solid-state image sensor 100 according to some other embodiments of the present disclosure. For example, FIG. 5A may be the partial cross-sectional view of the solid-state image sensor 100 along line C-C′ in FIG. 5B, but the present disclosure is not limited thereto. FIG. 5C is an enlarge view of the red color filter segment R1 in FIG. 5B. FIG. 5D is an enlarge view of the red color filter segment R2 in FIG. 5B. FIG. 5E is an enlarge view of the red color filter segment R3 in FIG. 5B. It should be noted that some components of the solid-state image sensor 100 have been omitted in FIG. 5A to FIG. 5E for the sake of brevity.

As shown in FIG. 5B (and FIG. 2), in some embodiments, the pillars 30Ra correspond to the corner region (that corresponds to the red color filter segments R3) of the red color filter layer 20R, the pillars 30Rb correspond to the peripheral region (that corresponds to the red color filter segments R2) of the red color filter layer 20R, and the pillar 30Ra correspond to the central region (that corresponds to the red color filter segment R1) of the red color filter layer 20R.

Similarly, in some embodiments, the pillars 30Ba correspond to the corner region (that corresponds to the blue color filter segments B3) of the blue color filter layer 20B, the pillars 30Bb correspond to the peripheral region (that corresponds to the blue color filter segments B2) of the blue color filter layer 20B, and the pillar 30Ba correspond to the central region (that corresponds to the blue color filter segment B1) of the blue color filter layer 20B.

Similarly, in some embodiments, the pillars 30Ga correspond to the corner region (that corresponds to the green color filter segments G3) of the green color filter layer 20G, the pillars 30Gb correspond to the peripheral region (that corresponds to the green color filter segments G2) of the green color filter layer 20G, and the pillar 30Ga correspond to the central region (that corresponds to the green color filter segment G1) of the green color filter layer 20G.

As shown in FIG. 5C to FIG. 5E, in some embodiments, the diameter d_{c} of the pillar 30Rc that corresponds to the central region of the red color filter layer 20R is smaller than the diameter dₐ of the pillar 30Ra that corresponds to the corner region of the red color filter layer 20R, and the diameter dₐ of the pillar 30Ra that corresponds to the corner region of the red color filter layer 20R is smaller than the diameter d_{b} of the pillar 30Rb that corresponds to the peripheral region of the red color filter layer 20R.

Similarly, in some embodiments, the diameter of the pillar 30Bc that corresponds to the central region of the blue color filter layer 20B is smaller than the diameter of the pillar 30Ba that corresponds to the corner region of the blue color filter layer 20B, and the diameter of the pillar 30Ba that corresponds to the corner region of the blue color filter layer 20B is smaller than the diameter of the pillar 30Bb that corresponds to the peripheral region of the blue color filter layer 20B.

Similarly, in some embodiments, the diameter of the pillar 30Gc that corresponds to the central region of the green color filter layer 20G is smaller than the diameter of the pillar 30Ga that corresponds to the corner region of the green color filter layer 20G, and the diameter of the pillar 30Ga that corresponds to the corner region of the green color filter layer 20G is smaller than the diameter of the pillar 30Gb that corresponds to the peripheral region of the green color filter layer 20G.

FIGS. 5F-5H respectively illustrate the three-dimensional schematic diagrams of the pillars 30Ra, 30Rb, 30Rc, the pillars 30Ga, 30Gb, 30Gc, and the pillars 30Ba, 30Bb, 30Bc. In some embodiments, the meta structure 30 includes additional caps 30oc disposed on the pillar 30Ra and the pillar 30Rc as shown in FIG. 5F, on the pillar 30Ga and the pillar 30Gc as shown in FIG. 5G, and/or on the pillar 30Ba and the pillar 30Bc as shown in FIG. 5G. For example, the additional cap 30oc may include oxide with low refractive index, but the present disclosure is not limited thereto.

In the embodiments of the present disclosure, the color filter segments in the central region form an n×n array, and the number of color filter segments in the peripheral region is 4n, and n is an integer greater than or equal to 1.

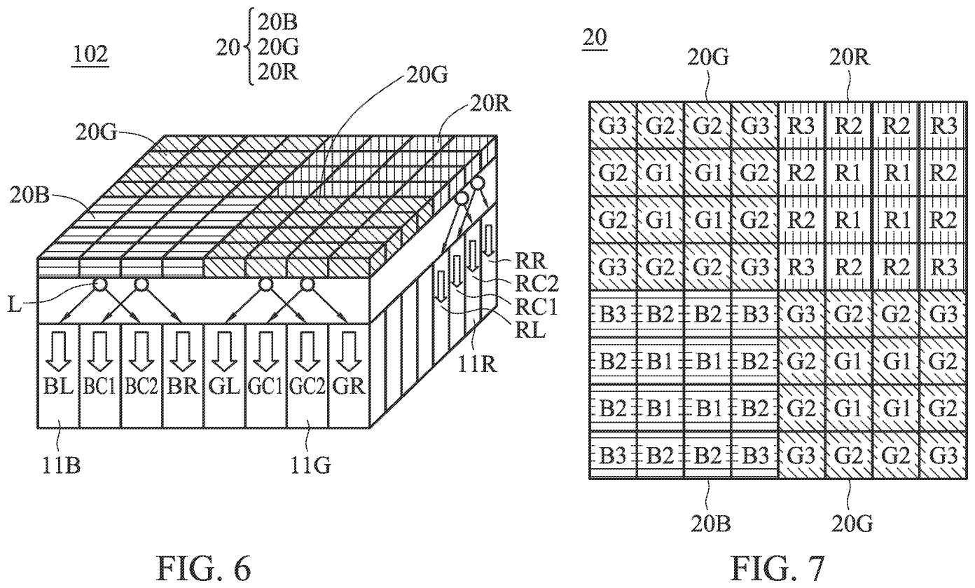

FIG. 6 is a schematic diagram of signal distribution of light passing through the solid-state image sensor 102 according to some embodiments of the present disclosure. FIG. 7 is a partial top view illustrating the color filter layer 20 of the solid-state image sensor 102. Similarly, some components of the solid-state image sensor 102 (e.g., the meta structure 30) have been omitted in FIG. 6 and FIG. 7 for the sake of brevity.

As shown FIG. 6, light passing through the meta structure 30 and the blue color filter segment B3 may be transferred into signal BL or signal BR and to be sensed by the photoelectric conversion element 11B, and light passing through the meta structure 30 and the blue color filter segment B2 may be transferred into signal BC1 or signal BC2 and to be sensed by the photoelectric conversion element 11B.

Similarly, light passing through the meta structure 30 and the green color filter segment G3 may be transferred into signal GL or signal GR and to be sensed by the photoelectric conversion element 11G, and light passing through the meta structure 30 and the green color filter segment G2 may be transferred into signal GC1 or signal GC2 and to be sensed by the photoelectric conversion element 11G.

Moreover, light passing through the meta structure 30 and the red color filter segment R3 may be transferred into signal RL or signal RR and to be sensed by the photoelectric conversion element 11R, and light passing through the meta structure 30 and the red color filter segment R2 may be transferred into signal RC1 or signal RC2 and to be sensed by the photoelectric conversion element 11R.

In this embodiment, L shown in FIG. 6 may be regarded as a splitter. That is, the energy of a raw image may be redistributed by the splitter L (i.e., passing through the meta structure 30), so that the spectral augmentation may be obtained. For example, signal processing for spectral information may be as follows:

$$( \begin{matrix}G 0 \\ GX\end{matrix} ) = ( \begin{matrix}\frac{1}{4} & \frac{1}{4} & \frac{1}{4} & \frac{1}{4} \\ \frac{1}{2} & - \frac{1}{2} & - \frac{1}{2} & \frac{1}{2}\end{matrix} ) ( \begin{matrix}GL \\ GC 1 \\ GC 2 \\ GR\end{matrix} )$$

Here, G0 represents a broad band information (i.e., a normal signal) in green color filter layer 20G, and GX represents a narrow band information (i.e., a specific signal) in green color filter layer 20G. In other words, GX represents a specific narrow band in green color filter layer 20G scattered by the splitter L. Therefore, signal GL, signal GC1, signal GC2, and signal GR may be, but not limited to, as follows:

$$\{ \begin{matrix}GL = G 0 + 0.5 GX \\ GC 1 = G 0 - GX + 0.5 GX = G 0 - 0.5 GX \\ GC 2 = G 0 - GX + 0.5 GX = G 0 - 0.5 GX \\ GR = G 0 + 0.5 GX\end{matrix}$$

Similarly, signal BL, signal BC1, signal BC2, and signal BR may be obtained by signal processing using B0 (i.e., a normal signal) and BX (i.e., a specific signal) in blue color filter layer 20B. Moreover, signal RL, signal RC1, signal RC2, and signal RR may be obtained by signal processing using R0 (i.e., a normal signal) and RX (i.e., a specific signal) in red color filter layer 20R), but the present disclosure is not limited thereto.

As shown in FIG. 7, the red color filter layer 20R has (or is divided into) red color filter segments R1, R2, and R3. In some embodiment, the red color filter layer 20R has a central region (that corresponds to the red color filter segments R1), a peripheral region (that corresponds to the red color filter segments R2) adjacent to the central region, and a corner region (that corresponds to the red color filter segments R3) diagonally arranged from the central region. In this embodiment, the red color filter segments R1 in the central region of the red color filter layer 20R form a 2×2 array, and the number of red color filter segments R2 in the peripheral region of the red color filter layer 20R is eight (4×2).

As shown in FIG. 7, the green color filter layer 20G has (or is divided into) green color filter segments G1, G2, and G3. Similarly, in some embodiment, the green color filter layer 20G has a central region (that corresponds to the green color filter segments G1), a peripheral region (that corresponds to the green color filter segments G2) adjacent to the central region, and a corner region (that corresponds to the green color filter segments G3) diagonally arranged from the central region. In this embodiment, the green color filter segments G1 in the central region of each green color filter layer 20G form a 2×2 array, and the number of green color filter segments G2 in the peripheral region of each green color filter layer 20G is eight (4×2).

As shown in FIG. 7, the blue color filter layer 20B has (or is divided into) blue color filter segments B1, B2, and B3. Similarly, in some embodiment, the blue color filter layer 20B has a central region (that corresponds to the blue color filter segments B1), a peripheral region (that corresponds to the blue color filter segments B2) adjacent to the central region, and a corner region (that corresponds to the blue color filter segments B3) diagonally arranged from the central region. In this embodiment, the blue color filter segments B1 in the central region of the blue color filter layer 20B form a 2×2 array, and the number of blue color filter segments B2 in the peripheral region of the blue color filter layer 20B is eight (4×2).

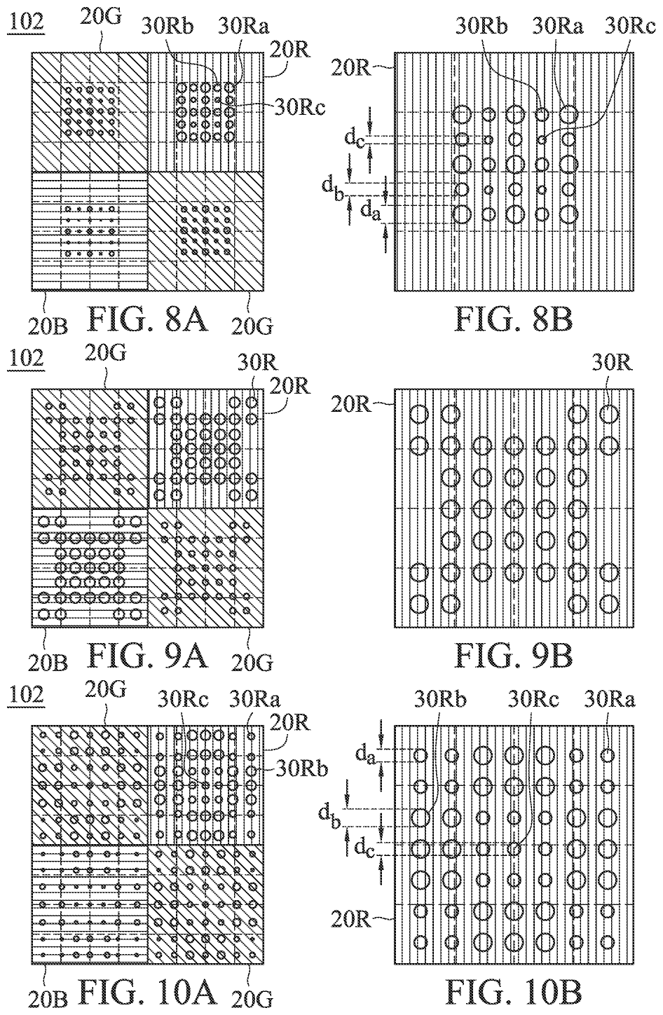

FIG. 8A is a partial top view illustrating the solid-state image sensor 102 according to some embodiments of the present disclosure. FIG. 8B is an enlarge view of the red color filter layer 20R and the corresponding pillars 30Ra, 30Rb, 30Rc in FIG. 8A.

As shown in FIG. 8A and FIG. 8B, in some embodiments, each red color filter segment (R1) in the central region is disposed under the pillars that are divided into a pillar 30Rc, pillars 30Rb arranged adjacent to the pillar 30Rc, and pillars 30Ra diagonally arranged from the pillar 30Rc. As shown in FIG. 8B, in some embodiments, the diameter d_{c} of the pillar 30Rc is smaller than the diameter d_{b} of the pillar 30Rb, and the diameter d_{b} of the pillar 30Rb is smaller than the diameter dₐ of the pillar 30Ra.

Similarly, as shown in FIG. 8A, the pillars that are disposed on the blue color filter layer 20B or the pillars that are disposed on the green color filter layer 20G may have similar arrangement to the pillars 30Ra, 30Rb, and 30Rc, which will not be repeated here, but the present disclosure is not limited thereto.

FIG. 9A is a partial top view illustrating the solid-state image sensor 102 according to some other embodiments of the present disclosure. FIG. 9B is an enlarge view of the red color filter layer 20R and the corresponding pillars 30R in FIG. 9A.

As shown in FIG. 9A and FIG. 9B, in some embodiments, the pillars 30R on the red color filter layer 20R have the same diameter. Similarly, as shown in FIG. 9A, in some embodiments, the pillars on the blue color filter layer 20B have the same diameter, and the pillars on the green color filter layer 20G have the same diameter.

FIG. 10A is a partial top view illustrating the solid-state image sensor 102 according to some other embodiments of the present disclosure. FIG. 10B is an enlarge view of the red color filter layer 20R and the corresponding pillars 30Ra, 30Rb, 30Rc in FIG. 10A.

As shown in FIG. 10A and FIG. 10B, in some embodiments, the pillars are divided into pillars 30Rc that correspond to the central region, pillars 30Rb that correspond to the peripheral region, and pillars 30Ra that correspond to the corner region, and the pillars 30Ra, 30Rb, and 30Rc have different diameters. In more detail, as shown in FIG. 10B, in some embodiments, the diameter d_{c} of the pillar 30Rc is equal to the diameter dₐ of the pillar 30Ra, and is smaller than the diameter d_{b} of the pillar 30Rb.

Similarly, as shown in FIG. 10A, the pillars that are disposed on the blue color filter layer 20B or the pillars that are disposed on the green color filter layer 20G may have similar arrangement to the pillars 30Ra, 30Rb, and 30Rc, which will not be repeated here, but the present disclosure is not limited thereto.

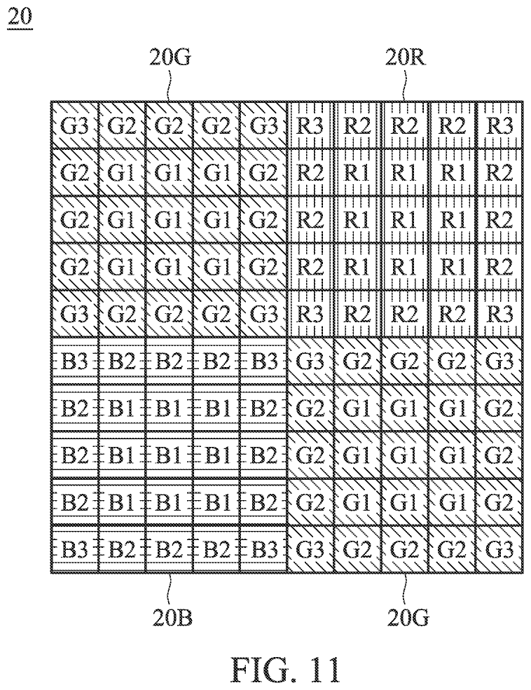

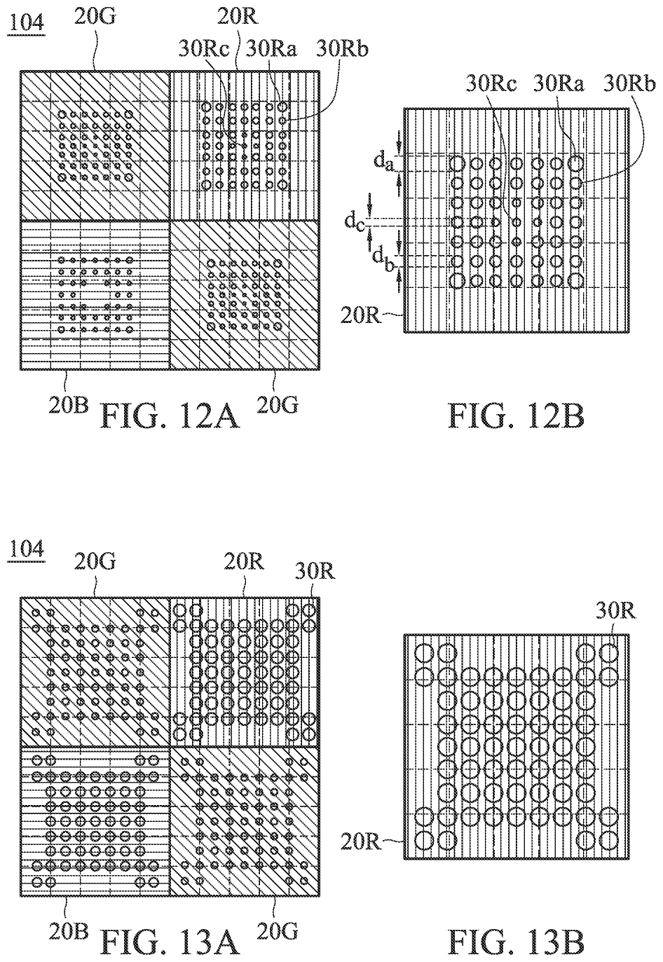

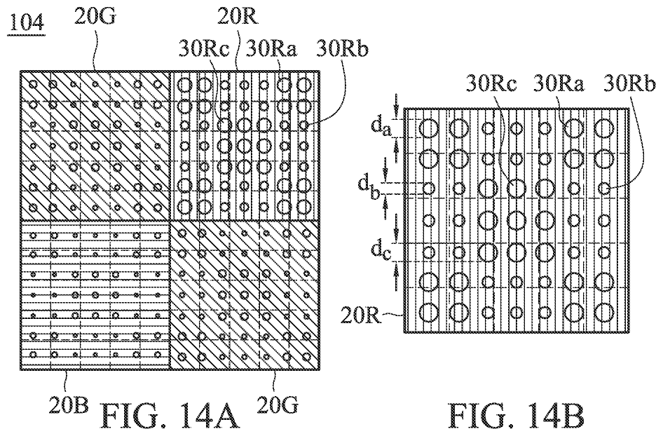

FIG. 11 is a partial top view illustrating the color filter layer 20 of the solid-state image sensor 104 (shown in FIG. 12A, FIG. 13A, and FIG. 14A). FIG. 12A is a partial top view illustrating the solid-state image sensor 104 according to some embodiments of the present disclosure. FIG. 12B is an enlarge view of the red color filter layer 20R and the corresponding pillars 30Ra, 30Rb, 30Rc in FIG. 12A. Similarly, some components of the solid-state image sensor 104 (e.g., the meta structure 30) have been omitted in FIG. 11, FIG. 12A, and FIG. 12B for the sake of brevity.

As shown in FIG. 11, the red color filter layer 20R has (or is divided into) red color filter segments R1, R2, and R3. In some embodiment, the red color filter layer 20R has a central region (that corresponds to the red color filter segments R1), a peripheral region (that corresponds to the red color filter segments R2) adjacent to the central region, and a corner region (that corresponds to the red color filter segments R3) diagonally arranged from the central region. In this embodiment, the red color filter segments R1 in the central region of the red color filter layer 20R form a 3×3 array, and the number of red color filter segments R2 in the peripheral region of the red color filter layer 20R is twelve (4×3).

As shown in FIG. 11, the green color filter layer 20G has (or is divided into) green color filter segments G1, G2, and G3. Similarly, in some embodiment, the green color filter layer 20G has a central region (that corresponds to the green color filter segments G1), a peripheral region (that corresponds to the green color filter segments G2) adjacent to the central region, and a corner region (that corresponds to the green color filter segments G3) diagonally arranged from the central region. In this embodiment, the green color filter segments G1 in the central region of each green color filter layer 20G form a 3×3 array, and the number of green color filter segments G2 in the peripheral region of each green color filter layer 20G is twelve (4×3).

As shown in FIG. 11, the blue color filter layer 20B has (or is divided into) blue color filter segments B1, B2, and B3. Similarly, in some embodiment, the blue color filter layer 20B has a central region (that corresponds to the blue color filter segments B1), a peripheral region (that corresponds to the blue color filter segments B2) adjacent to the central region, and a corner region (that corresponds to the blue color filter segments B3) diagonally arranged from the central region. In this embodiment, the blue color filter segments B1 in the central region of the blue color filter layer 20B form a 3×3 array, and the number of blue color filter segments B2 in the peripheral region of the blue color filter layer 20B is twelve (4×3).

As shown in FIG. 12A and FIG. 12B, in some embodiments, the pillars are divided into pillars 30Rc that form an x shape and correspond to the middle of the central region, pillars 30Rb that surround the pillars 30Rc, and pillars 30Ra that correspond to four corners of the central region. In more detail, as shown in FIG. 12B, in some embodiments, the diameter d_{c} of the pillar 30Rc is smaller than the diameter d_{b} of the pillar 30Rb, and the diameter d_{b} of the pillar 30Rb is smaller than the diameter dₐ of the pillar 30Ra.

Similarly, as shown in FIG. 12A, the pillars that are disposed on the blue color filter layer 20B or the pillars that are disposed on the green color filter layer 20G may have similar arrangement to the pillars 30Ra, 30Rb, and 30Rc, which will not be repeated here, but the present disclosure is not limited thereto.

FIG. 13A is a partial top view illustrating the solid-state image sensor 104 according to some other embodiments of the present disclosure. FIG. 13B is an enlarge view of the red color filter layer 20R and the corresponding pillars 30R in FIG. 13A.

As shown in FIG. 13A and FIG. 13B, in some embodiments, the pillars 30R on the red color filter layer 20R have the same diameter. Similarly, as shown in FIG. 13A, in some embodiments, the pillars on the blue color filter layer 20B have the same diameter and the pillars on the green color filter layer 20G have the same diameter.

FIG. 14A is a partial top view illustrating the solid-state image sensor 104 according to some other embodiments of the present disclosure. FIG. 14B is an enlarge view of the red color filter layer 20R and the corresponding pillars 30Ra, 30Rb, 30Rc in FIG. 14A.

In some embodiments, the pillars are divided into pillars 30Rc that form a p×p array and correspond to the middle of the red color filter layer 20R, pillars 30Rb that surround the pillars 30Rc, and pillars 30Ra that form a q×q array and correspond to four corners of the red color filter layer 20R, and p and q are integers greater than or equal to 2. In the embodiment shown in FIG. 14A and FIG. 14B, p=3 and q=2, but the present disclosure is not limited thereto. Moreover, as shown in FIG. 14B, in some embodiments, the diameter d_{c} of the pillar 30Rc is equal to the diameter dₐ of the third pillar 30Ra, and is smaller than the diameter d_{b} of the pillar 30Rb.

Similarly, as shown in FIG. 14A, the pillars that are disposed on the blue color filter layer 20B or the pillars that are disposed on the green color filter layer 20G may have similar arrangement to the pillars 30Ra, 30Rb, and 30Rc, which will not be repeated here, but the present disclosure is not limited thereto.

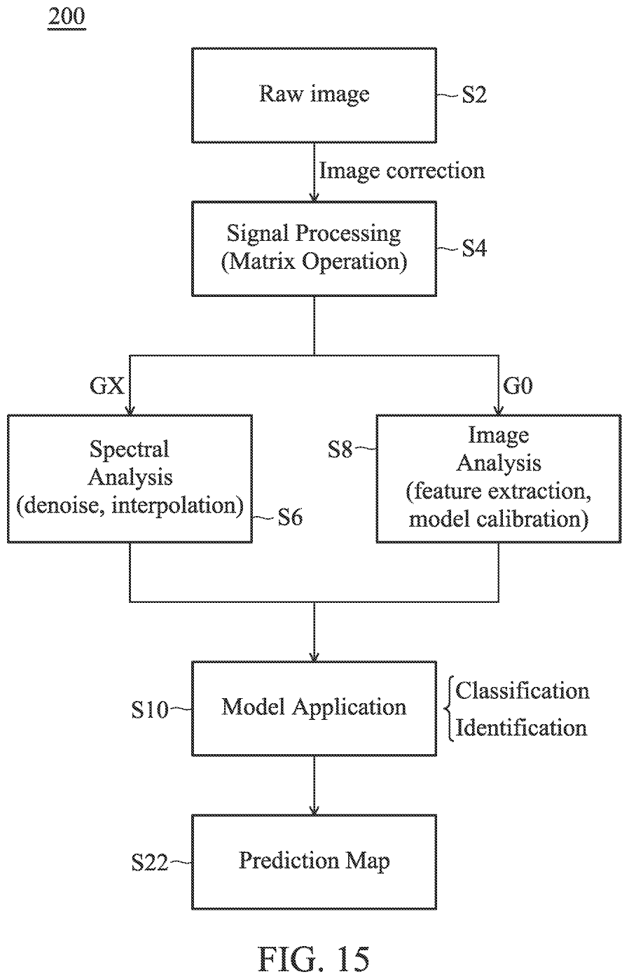

FIG. 15 is a flow chart 200 illustrating a method for an image signal processing. In step S2, a raw image is input into the solid-state image sensor (e.g., the solid-state image sensor 100, 102, or 104). Then, in step S4, a signal processing (e.g., matrix operation as mentioned above) is performed to obtain a normal signal (e.g., G0) and a specific signal (e.g., GX). In more detail, an image correction is performed on the raw image, so that the solid-state image sensor (e.g., the solid-state image sensor 100, 102, or 104) obtains the normal signal and the specific signal according to the embodiments of the present disclosure. In step S6, the specific signal (e.g., GX) is used for spectral analysis (e.g., denoise, interpolation, and so on). In step S8, the normal signal (e.g., G0) is used for image analysis (e.g, feature extraction, model calibration, and so on). Then, in step S10, the normal signal (e.g., G0) and the specific signal (e.g., GX) are integrated to form a specific model (e.g., for classification, identification, and so on). Then, in step S22 the specific model is output from the solid solid-state image sensor from the solid-state image sensor (e.g., the solid-state image sensor 100, 102, or 104) to obtain a prediction map.

As noted above, the solid-state image sensor according to the embodiments of the present disclosure includes a meta structure, the pillars that correspond to the central region, the peripheral region, and the corner region of the color filter layer have different arrangements. Therefore, the augmented spectroscopic information with medium linewidth (e.g., Δλ is about 15-50 nm) may be obtained by the solid-state image sensor without large multispectral image cubes.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A solid-state image sensor, comprising:
photoelectric conversion elements;
a color filter layer disposed above the photoelectric conversion elements and comprising a first color filter layer, wherein the first color filter layer has a central region, a peripheral region adjacent to the central region, and a corner region diagonally arranged from the central region;
a meta structure disposed on the color filter layer and comprising pillars, wherein the pillars that correspond to the central region, the peripheral region, and the corner region have different arrangements.

2. The solid-state image sensor as claimed in claim 1, wherein the pillars correspond to the central region.

3. The solid-state image sensor as claimed in claim 2, wherein the pillars are divided into a first pillar, second pillars, and third pillars with different diameters and form an array.

4. The solid-state image sensor as claimed in claim 3, wherein the second pillars are arranged adjacent to the first pillar, and the third pillars are diagonally arranged from the first pillar, and a diameter of the first pillar is smaller than a diameter of each of the second pillars, and the diameter of each of the second pillars is smaller than a diameter of each of the third pillars.

5. The solid-state image sensor as claimed in claim 1, wherein the pillars correspond to the central region and the corner region, and the pillars have the same diameter.

6. The solid-state image sensor as claimed in claim 1, wherein the pillars correspond to the central region, the peripheral region, and the corner region.

7. The solid-state image sensor as claimed in claim 6, wherein the pillars are divided into a first pillar that corresponds to the central region, second pillars that correspond to the peripheral region, and third pillars that correspond to the corner region, and the first pillar, the second pillars, and the third pillars have different diameters.

8. The solid-state image sensor as claimed in claim 7, wherein a diameter of the first pillar is smaller than a diameter of each of the third pillars, and the diameter of each of the third pillars is smaller than a diameter of each of the second pillars.

9. The solid-state image sensor as claimed in claim 7, wherein the meta structure comprises additional caps disposed on the first pillar and the third pillars.

10. The solid-state image sensor as claimed in claim 1, wherein the first color filter layer has first color filter segments, the first color filter segments in the central region form an n×n array, and the number of first color filter segments in the peripheral region is 4n, and n is an integer greater than or equal to 1.

11. The solid-state image sensor as claimed in claim 10, wherein n is 2, and each of the first color filter segments in the central region is disposed under the pillars that are divided into a first pillar, second pillars arranged adjacent to the first pillar, and third pillars diagonally arranged from the first pillar.

12. The solid-state image sensor as claimed in claim 11, wherein a diameter of the first pillar is smaller than a diameter of each of the second pillars, and the diameter of each of the second pillars is smaller than a diameter of each of the third pillars.

13. The solid-state image sensor as claimed in claim 10, wherein n is 2, and the pillars are divided into first pillars that correspond to the central region, second pillars that correspond to the peripheral region, and third pillars that correspond to the corner region, and the first pillar, the second pillars, and the third pillars have different diameters.

14. The solid-state image sensor as claimed in claim 13, wherein a diameter of each of the first pillars is equal to a diameter of each of the third pillars, and is smaller than a diameter of each of the second pillars.

15. The solid-state image sensor as claimed in claim 10, wherein n is 3, and the pillars are divided into first pillars that form an x shape and correspond to the middle of the central region, second pillars that surround the first pillars, and third pillars that correspond to four corners of the central region.

16. The solid-state image sensor as claimed in claim 15, wherein a diameter of each of the first pillars is smaller than a diameter of each of the second pillars, and the diameter of each of the second pillars is smaller than a diameter of each of the third pillars.

17. The solid-state image sensor as claimed in claim 10, wherein n is 3, and the pillars are divided into first pillars that form a p×p array and correspond to the middle of the first color filter layer, second pillars that surround the first pillars, and third pillars that form a q×q array and correspond to four corners of the first color filter layer, wherein p and q are integers greater than or equal to 2.

18. The solid-state image sensor as claimed in claim 17, wherein a diameter of each of the first pillar is equal to a diameter of each of the third pillars, and is smaller than a diameter of each of the second pillars.

19. The solid-state image sensor as claimed in claim 1, wherein the color filter layer further comprises a second color filter layer that is adjacent to the first color filter layer and corresponds to different colors than the first color filter layer, and the pillars have different heights on the first color filter layer and the second color filter layer.

20. A method for an image signal processing, comprising:
inputting a raw image into a solid solid-state image sensor, wherein the solid solid-state image sensor comprises:
photoelectric conversion elements;
a color filter layer disposed above the photoelectric conversion elements and comprising a first color filter layer, wherein the first color filter layer has a central region, a peripheral region adjacent to the central region, and a corner region diagonally arranged from the central region;
a meta structure disposed on the color filter layer and comprising pillars, wherein the pillars that correspond to the central region, the peripheral region, and the corner region have different arrangements;
performing an image correction on the raw image, so that the solid-state image sensor obtains a normal signal and a specific signal with matrix operation;
integrating the normal signal and the specific signal to form a specific model; and
outputting the specific model from the solid solid-state image sensor to obtain a prediction map.
